(19) United States
(12) Patent Application Publication
(10) Pub. No.: US 2012/0167824 A1
(43) Pub. Date: Jul. 5, 2012

(54) CVD APPARATUS

(76) Inventors: Jong Sun MAENG, Gwangju (KR); Ki Sung Kim, Suwon (KR); Bum Joon Kim, Seoul (KR); Hyun Seok Ryu, Suwon (KR); Sung Tae Kim, Seoul (KR)

(21) Appl. No.: 13/285,596

(22) Filed: Oct. 31, 2011

(30) Foreign Application Priority Data
Jan. 4, 2011 (KR) 10-2011-0000537

(51) Int. Cl. H01L 21/00; C23C 16/458; C23C 16/455

(52) U.S. Cl. 118/724

(57) ABSTRACT

A chemical vapor deposition (CVD) apparatus, including: a reaction chamber including an internal chamber having an internal space, an external chamber configured to cover the internal chamber so as to maintain a sealing state thereof; a wafer holder disposed within the internal chamber for a plurality of wafers stacked therein; a gas supplier including an inner pipe having an inner path, an external pipe having an external path, a refrigeration pipe having a cooling path. The inner path of the inner pipe supplies a first process gas into the reaction chamber. The external path of the external pipe surrounds the inner pipe to supply a second process gas therethrough. The refrigeration pipe supplies a refrigerant to prevent temperature rise in the inner pipe.

### CROSS-REFERENCE TO RELATED APPLICATIONS

This application claims the priority of Korean Patent Application No. 10-2011-0000537 filed on Jan. 4, 2011, in the Korean Intellectual Property Office, the disclosure of which is incorporated herein by reference.

### BACKGROUND OF THE INVENTION

1. Field of the Invention

The present invention relates to a chemical vapor deposition apparatus.

2. Description of the Related Art

Demand for light emitting diodes (LEDs) has greatly increased in the fields of various electronic products including a mobile phone keypad, an LCD, a TV backlighting unit (BLU) and a general illumination system. In order to satisfy this demand, research into the introduction of a large-diameter sapphire wafer, for example, using a 6-inch sapphire wafer in the place of a 4-inch sapphire wafer, or the like, and into batch-type metalorganic chemical vapor deposition (MOCVD) technology for the performing of an epitaxial thin film growth process for a large number of wafers in a batch during mass production has been conducted, the sapphire wafer being used in the process in which a nitride or oxide semiconductor (for example, GaN, ZnO) applicable to a light emitting device is grown to have an epitaxial thin film.

As the method to employ this technology, research into a hot-wall reactor is conducted, but there have been difficulties in attaining a high-temperature deposition to get high crystallinity due to the properties of an MO source in which the MO source is decomposed at a relatively low temperature, for example, at about 500□ or less.

### SUMMARY OF INVENTION

An aspect of the present invention provides a chemical vapor deposition (CVD) apparatus capable of preventing a nozzle from being blocked due to an early decomposition of an MO source by eliminating a factor interfering with the uniformity in a thin film growth between wafers, thereby achieving CVD layers improved in quality and reliability.

According to an aspect of the present invention, there is provided a CVD apparatus including: aa reaction chamber including an internal chamber having an internal space, and an external chamber configured to cover the internal chamber so as to maintain a sealing state thereof; a wafer holder disposed within the internal chamber and configured to receive a plurality of wafers stacked therein; and a gas supplier including an inner pipe having an inner path, an external pipe having an external path, and a refrigeration pipe having a cooling path, the inner path of the inner pipe being for supplying a first process gas into the reaction chamber therethrough to allow a semiconductor epitaxial thin film to be grown on a surface of the respective wafers, the external path of the external pipe being disposed to surround the inner pipe to supply a second process gas therethrough, and the cooling path of the refrigeration pipe being disposed between the inner pipe and the external pipe to supply a refrigerant therethrough to prevent a temperature rise in the inner pipe.

The gas supplier may have an overlapping layout structure in which the inner pipe is disposed to be overlapped with the refrigerant pipe on an inner circumferential surface of the external pipe.

In addition, the external pipe may include a plurality of spray nozzles connecting the external path to the reaction chamber and spraying the second process gas of the external path into the reaction chamber, the plurality of spray nozzles being arrayed on a circumferential surface thereof adjacent to the spray pipes.

In the case of the spray pipe, a plurality of spray pipes may be arrayed to correspond to intervals between the stacked wafers along the overlapping surfaces of the refrigerant pipe and the external pipe.

The external pipe may include a plurality of spray nozzles connecting the external path to the reaction chamber and spraying the second process gas of the external path into the reaction chamber, the plurality of spray nozzles being arrayed on a circumferential surface thereof adjacent to the spray pipes.

In addition, in the case of the gas supplier, a plurality of gas suppliers may be disposed to be spaced apart from one another along a circumference of the wafer holder, and the respective gas suppliers may have different heights corresponding to heights of respective regions in which the wafer holder is divided into several sections in a vertical direction thereof.

The gas supplier may include a first supplier supplying the process gas to a lower region of the wafer holder, a second supplier supplying the process gas to a center region of the wafer holder, and a third supplier supplying the process gas to an upper region of the wafer holder.

In addition, the gas suppliers may be respectively connected to flow meters that control a supplied amount of the process gas, so as to control supplied amounts of the process gas independently of one another.

### BRIEF DESCRIPTION OF DRAWINGS

The above and other aspects, features and other advantages of the present invention will be more clearly understood from the following detailed description taken in conjunction with the accompanying drawings, in which:

FIG. 1 is a cross-sectional view of a CVD apparatus according to an embodiment of the present invention;

FIG. 2 is a schematic perspective view of a gas supplier in the CVD apparatus shown in FIG. 1;

FIG. 3 is a cross-sectional view of the gas supplier shown in FIG. 2;

FIG. 4 is a schematic perspective view showing a layout structure of the gas suppliers according to respective regions of the wafer holder of the CVD apparatus of FIG. 1;

FIG. 5 is a perpendicularly cross-sectional view showing the layer structure of FIG. 4; and

FIG. 6 is a cross-sectional view showing the layer structure of FIG. 4.

### DETAILED DESCRIPTION OF PREFERRED EMBODIMENT

Exemplary embodiments of the present invention will now be described in detail with reference to the accompanying drawings such that they could be easily practiced by those having skill in the art to which the present invention pertains. However, in describing the exemplary embodiments of the present invention, detailed descriptions of well-known functions or constructions will be omitted so as not to obscure the description of the present invention with unnecessary detail.

In addition, like reference numerals denote like elements throughout the drawings.

Unless explicitly described to the contrary, the word “comprise” and variations such as “comprises” or “comprising,” will be understood to imply the inclusion of stated elements but not the exclusion of other elements.

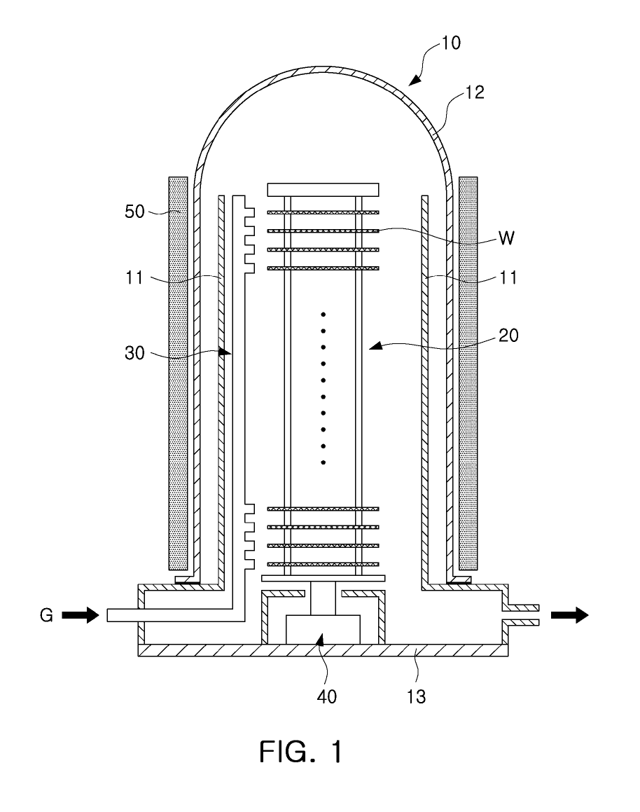

According to an embodiment of the present invention, a chemical vapor deposition (CVD) apparatus will be described with reference to FIGS. 1 to 6.

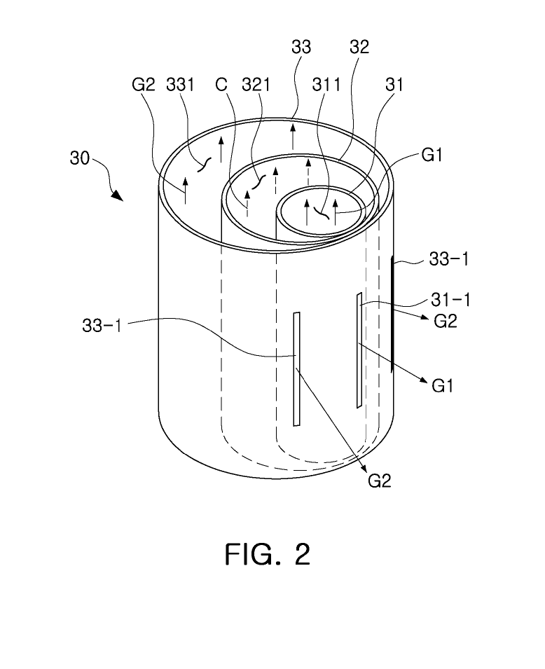

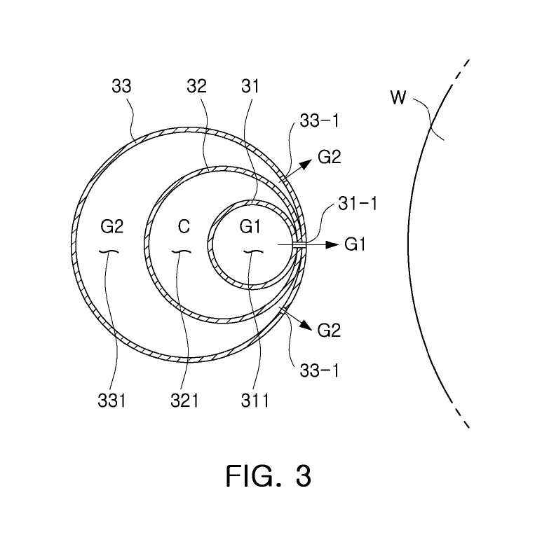

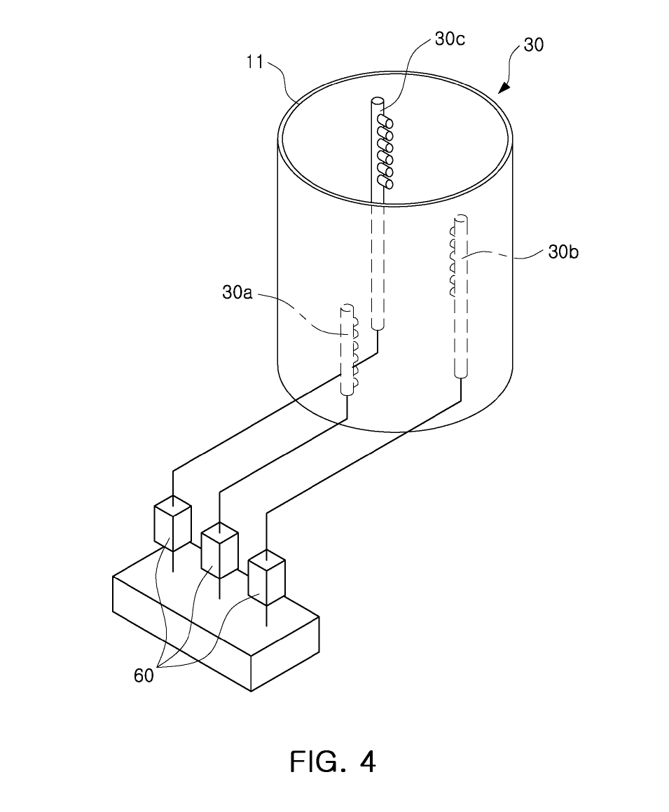

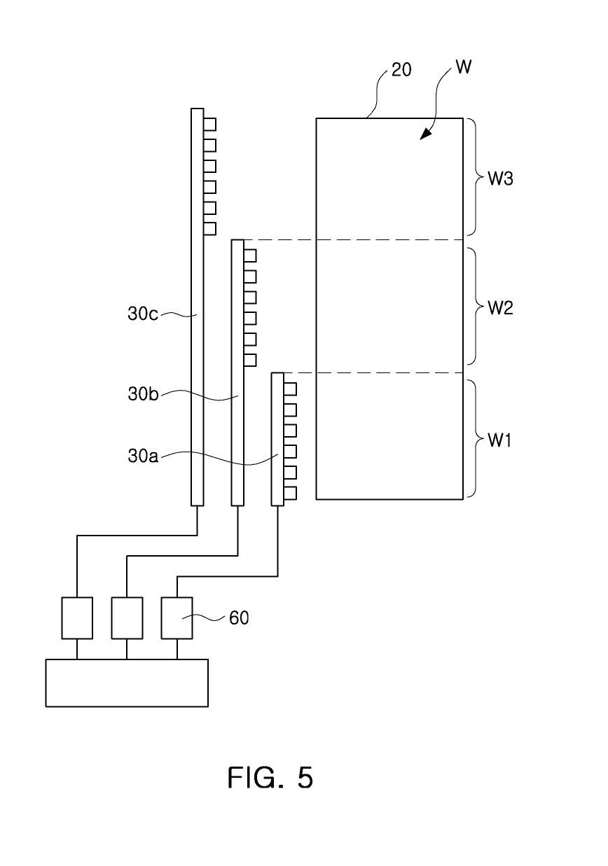

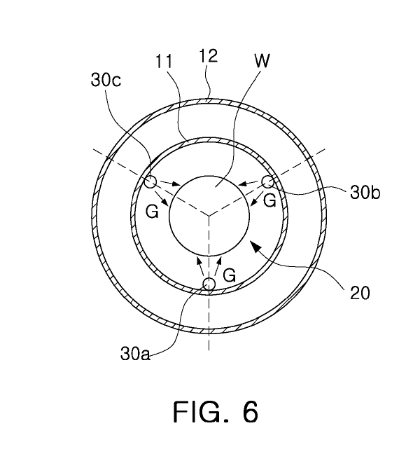

FIG. 1 is a cross-sectional view of a CVD apparatus according to an embodiment of the present invention. FIG. 2 is a schematic perspective view of a gas supplier in the CVD apparatus shown in FIG. 1. FIG. 3 is a cross-sectional view of the gas supplier shown in FIG. 2. FIG. 4 is a schematic perspective view showing a layout structure of the gas suppliers according to respective regions of the wafer holder of the CVD apparatus of FIG. 1. FIG. 5 is a perpendicularly cross-sectional view showing the layer structure of FIG. 4. FIG. 6 is a cross-sectional view showing the layer structure of FIG. 4.

Referring to FIGS. 1 to 6, a CVD apparatus 1 according to an embodiment of the present invention may be configured to include a reaction chamber 10, a wafer holder 20 and a gas supplier 30. The CVD apparatus 1 may further include a rotation driving part 40 that is connected to the wafer holder 20 to rotate the wafer holder 20. Also, the CVD apparatus may further include a heating unit 50 disposed around a circumference of the reaction chamber 10 to heat the reaction chamber 10. Through the heating unit 50, the reaction chamber 10 may be maintained to have a relatively high uniform temperature.

The reaction chamber 10 may be configured to have a double structure including an internal chamber 11 and an external chamber 12. The internal chamber 11 of the reaction chamber 10 may be cylindrical and have opened upper and lower parts, and may be configured to have an internal space of a predetermined size. The external chamber 12 of the reaction chamber 10 may be configured to have an opened lower structure and cover the internal chamber 11 so as to maintain a sealing state of the internal chamber 11. In addition, the internal chamber 11 may be provided with a base plate 13 disposed on the lower part of the internal chamber 11. The base plate 13 may be disposed at a lower part of the internal chamber 11 to open or close the internal chamber 11. The internal chamber 11, the external chamber 12 and the base plate 13 may be formed of quartz or SiC.

In the case of the wafer holder 20, a plurality of wafers W for a thin film growth process may be stacked therein to be spaced apart from one another at predetermined intervals. The wafer holder 20, in which the wafers W are stacked, may be disposed within the internal chamber 11, or discharged to the outside, by the base plate 13 to open or close the internal chamber. The wafer holder 20 may be formed of a material such as quartz or the like so as to prevent the wafer holder 20 from being transformed within the reaction chamber 10 having a high-temperature and high pressure atmosphere, but is not limited thereto.

As such, hundreds of wafers W may be stacked so as to be spaced apart from one another at predetermined intervals in the wafer holder 20, thereby allowing for the mass production of the thin-film growth process on wafers, as compared with a related art in which only several wafers W may be stacked on a susceptor so as to have thin films grown thereon.

The wafer holder 20 may be configured to be connected to the rotation driving unit 40 protected by a heat insulating plate so as to rotate at a predetermined speed by a rotation force applied from the rotation driving unit 50 within the internal chamber 11. Therefore, an epitaxial thin film may be uniformly grown on the entire surface of the wafer W.

The gas supplier 30 may supply a process gas from the outside into the reaction chamber 10 such that a semiconductor epitaxial thin film is grown on the surface of the respective wafers W. In detail, the gas supplier 30 may be formed to vertically extend in a stacking direction of the wafers W between the internal chamber 11 and the wafer holder 20. As shown in FIGS. 1 to 6, the gas supplier 30 may be configured to include an inner pipe 31 having an inner path 311, an external pipe 33 having an external path 331, and a refrigeration pipe 32 having a cooling path 321, to have a triple pipe structure. Herein, the inner path 311 of the inner pipe 31 may supply a first process gas G1 therethrough. The external path 331 of the external pipe 33 may be configured to surround the inner pipe 31 to supply a second process gas G2 therethrough. The cooling path 321 of the refrigeration pipe 32 may be disposed between the inner pipe 31 and the external pipe 33 to supply a refrigerant C therethrough so as to prevent a temperature rise in the inner pipe 31.

The process gas G may be classified into the first process gas G1 and the second process gases G2, and the first process gas G1 may contain an MO source and the second process gas G2 may contain NH₃, H₂, or the like.

As shown in FIGS. 2 and 3, the gas supplier 30 may have an overlapping layout structure in which the inner pipe 31 is disposed to be overlapped with the refrigerant pipe 32 on an inner circumferential surface of the external pipe 33. By this structure, the inner pipe 31 may be stably fixed to the refrigerant pipe 32 within the external pipe 33.

The inner pipe 31 may be connected to the inner path 311 that is configured to penetrate through the refrigerant pipe 32 and the external pipe 33 on an overlapping surface thereof. The inner pipe 31 may be configured to include a spray pipe 31-1 spraying the first process gas G1 of the inner path 311 into the reaction chamber 10. In the case of the spray pipe 31-1, a plurality of spray pipes 31-1 may be arrayed to correspond to intervals between the stacked wafers W along the overlapping surfaces of the refrigerant pipe 32 and the external pipe 33.

Meanwhile, the external pipe 33 may be connected to the external path 331 and configured to include a spray nozzle 33-1 spraying the second process gas G2 of the external path 331 into the reaction chamber 10. The spray nozzles 33-1 may be arrayed on a circumferential surface thereof adjacent to the spray pipes 31-1. That is, the spray pipes 33-1 may be disposed at both sides or any one side based on a position on which the spray pipes 31-1 are disposed, and may be arrayed to correspond to intervals between the stacked wafers W, in the manner similar to the spray pipes 31-1.

The spray pipes 31-1 and the spray nozzles 33-1 may be disposed to correspond to the position on which the wafers W are disposed, along a length direction of the gas supplier 30. Therefore, the spray pipes 31-1 and the spray nozzles 33-1 may be arrayed to correspond to intervals between the stacked wafers W so as to be opposed to respective side parts of the stacked wafers W, or may be arrayed to be located between the stacked wafers W. By this layout structure, the spray pipes 31-1 and the spray nozzles 33-1 may spray the first and second process gases G1 and G2 to the surfaces of the respective wafers W, for example, only to an upper surface thereof, or to upper and lower surfaces of the wafer W such that epitaxial thin films may be simultaneously deposited on the upper and lower surfaces of the respective wafers W.

In order to enhance the uniformity of the epitaxial thin film grown on the respective wafers W, a plurality of gas suppliers 30 may be disposed to be spaced apart from one another at constant intervals along a circumference of the wafer holder 20. The respective gas suppliers 30 may be formed to have different heights corresponding to heights of respective regions in which the wafer holder 20 is divided into several sections in a vertical direction thereof that corresponds to a stacking direction of the wafers W stacked in the wafer holder 20.

Described in detail, as shown in FIG. 5, for example, when the wafer holder 20 is divided into three, a lower region W1, a center region W2 and an upper region W3, the gas supplier 30 may be formed to include a first supplier 30a supplying the process gas G to the lower region W1 of the wafer holder 20; a second supplier 30b supplying the process gas to the center region W2 of the wafer holder 20; and a third supplier 30c supplying the process gas G to the upper region W3 of the wafer holder 20. Herein, the first supplier 30a may be formed to have a height to corresponding to a height of the lower region W1, the second supplier 30b may be formed to have a height corresponding to a height of the center region W2, and the third supplier 30c may be formed to have a height corresponding to a height of the upper region W3.

The gas suppliers 30 may be respectively connected to flow meters 60 that control a supplied amount of the process gas G, so as to control supplied amounts of the process gas G independently of one another. In other words, the amounts of the process gas G supplied to the respective gas suppliers 301, 30b and 30c may be separately controlled using the flow meters 60 respectively connected to the first, second and third suppliers 301, 30b and 30c.

Therefore, the respective gas suppliers 30a, 30b and 30c disposed to correspond to the respective regions of the wafer holder 20 may control supplied amounts of the process gas G such that amounts of gas appropriate to respective regions are supplied, by using the flow meters 60 that are disposed to correspond to respective gas suppliers. Whereby, thin films may be simply prevented from the occurrence of a difference in uniformity according to the respective regions W1, W2 and W3, without determining a temperature gradient or the like on the regions of the wafer holder 20 divided in a vertical direction.

As set forth above, according to an embodiment of the present invention, an inner pipe through which a process gas flows is configured to be surrounded by a refrigerant pipe through which a refrigerant flows, such that the process gas flowing in the inner pipe may be prevented from being heat degraded prior to a spraying of the process gas to a wafer, thereby preventing the inner pipe from being blocked and occurring in breakage therein.

In addition, uniformity in the growth of epitaxial thin films formed across the entire stacked wafers may be maintained, thereby achieving products improved in quality and reliability.

Further, according to an embodiment of the present invention, as shown in FIG. 6, the first, second and third suppliers 30a, 30b and 30c may be configured to be spaced apart from one another at constant intervals along a circumference of the wafer holder 20, such that the process gas G is sprayed and uniformly supplied, thereby improving the uniformity of thin films.

While the present invention has been shown and described in connection with the exemplary embodiments, it will be apparent to those skilled in the art that modifications and variations can be made without departing from the spirit and scope of the invention as defined by the appended claims.

What is claimed is:

1. A chemical vapor deposition (CVD) apparatus, comprising:
a reaction chamber including an internal chamber having an internal space, and an external chamber configured to cover the internal chamber so as to maintain a sealing state thereof;
a wafer holder disposed within the internal chamber and configured to receive a plurality of wafers stacked therein; and
a gas supplier including an inner pipe having an inner path, an external pipe having an external path, and a refrigeration pipe having a cooling path, the inner path of the inner pipe being for supplying a first process gas into the reaction chamber therethrough to allow a semiconductor epitaxial thin film to be grown on a surface of the respective wafers, the external path of the external pipe being disposed to surround the inner pipe to supply a second process gas therethrough, and the cooling path of the refrigeration pipe being disposed between the inner pipe and the external pipe to supply a refrigerant therethrough to prevent a temperature rise in the inner pipe.

2. The apparatus of claim 1, wherein the gas supplier has an overlapping layout structure in which the inner pipe is disposed to be overlapped with the refrigerant pipe on an inner circumferential surface of the external pipe.

3. The apparatus of claim 2, wherein the inner pipe includes a plurality of spray pipes configured to penetrate through the refrigerant pipe and the external pipe on an overlapping surface thereof and connect the inner path to the reaction chamber, the plurality of spray pipes spraying the first process gas of the inner path into the reaction chamber.

4. The apparatus of claim 3, wherein the plurality of spray pipes are arrayed to correspond to intervals between the stacked wafers along the overlapping surfaces of the refrigerant pipe and the external pipe.

5. The apparatus of claim 3, wherein the external pipe includes a plurality of spray nozzles connecting the external path to the reaction chamber and spraying the second process gas of the external path into the reaction chamber, the plurality of spray nozzles being arrayed on a circumferential surface thereof adjacent to the spray pipes.

6. The apparatus of claim 1, wherein the gas supplier has a layout structure in which a plurality of gas suppliers are disposed to be spaced apart from one another along a circumference of the wafer holder, and the respective gas suppliers have different heights corresponding to heights of respective regions in which the wafer holder is divided into several sections in a vertical direction thereof.

7. The apparatus of claim 6, wherein the gas supplier includes a first supplier supplying the process gas to a lower region of the wafer holder, a second supplier supplying the process gas to a center region of the wafer holder, and a third supplier supplying the process gas to an upper region of the wafer holder.

8. The apparatus of claim 6, wherein the gas suppliers are respectively connected to flow meters that control a supplied amount of the process gas, so as to control supplied amounts of the process gas independently of one another.
